(19) United States
(12) Patent Application Publication
(10) Pub. No.: US 2025/0371505 A1
(43) Pub. Date: Dec. 4, 2025

(54) METHOD FOR MONITORING PROPER FUNCTIONING OF ONE OR MORE COMPONENTS OF A LITHOGRAPHY SYSTEM

(71) Applicant: ASML Netherlands B.V., Veldhoven (NL)

(72) Inventors: Bram Paul Theodoor VAN GOCH, Maarheeze (NL); Richard Jacobus Rudolf VAN DER MAAS, Eindhoven (NL)

(73) Assignee: ASML Netherlands B.V., Veldhoven (NL)

(21) Appl. No.: 18/873,609

(22) PCT Filed: Aug. 14, 2023
(86) PCT No.: PCT/EP2023/072412

§ 371 Date: Dec. 10, 2024

(30) Foreign Application Priority Data
Sep. 6, 2022 (EP) 22194094.3

(51) Int. Cl. G06Q 10/20; G03F 7/00

(52) U.S. Cl. CPC G06Q 10/20; G03F 7/70508; G03F 7/70516; G03F 7/70533; G03F 7/707; G03F 7/70716

(57) ABSTRACT

Disclosed is a method for monitoring proper functioning of one or more components of a lithography system. The method comprises determining a frequency response function for each of said one or more components during production activity using the lithography system, at a time during said production activity when control requirements are relatively less stringent; evaluating each of said frequency response functions with respect to control data indicative of nominal lithographic system behavior; and predicting whether to perform a maintenance action on the lithography system based on said evaluating step.

### CROSS-REFERENCE TO RELATED APPLICATIONS

This application claims priority of EP application Ser. No. 22194094.3 which was filed on Sep. 6, 2022 and which is incorporated herein in its entirety by reference.

### FILED OF THE INVENTION

The present invention relates to methods and apparatus usable, for example, in the manufacture of devices by lithographic techniques, and to methods of manufacturing devices using lithographic techniques. The invention relates more particularly to failure detection for such devices.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110,027704A, US20110043791A, US2011102753A1US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

A lithographic system is a very complex tool comprising multiple components, many of which require very stringent control to achieve a patterning accuracy at nanometer scale and at an acceptable speed. Uptime of such systems is important, and any downtime represents a significant overhead.

However, it is presently necessary to take the systems offline to measure the frequency response function of system components, so as to determine whether they are functioning correctly or whether a maintenance action is required. It would be desirable to improve on such lithographic system maintenance methods.

### SUMMARY OF THE INVENTION

The invention in a first aspect provides a method for monitoring proper functioning of one or more components of a lithography system, the method comprising: determining a frequency response function for each of said one or more components during production activity using the lithography system, at a time during said production activity when control requirements are relatively less stringent;

evaluating each of said frequency response functions with respect to control data indicative of nominal lithographic system behavior; and predicting whether to perform a maintenance action on the lithography system based on said evaluating step.

Also disclosed is a computer program and lithographic system being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus; and

FIG. 2 illustrates schematically measurement and exposure processes in the apparatus of FIG. 1.

### DETAILED DESCRIPTION OF EMBODIMENTS

Before describing embodiments of the invention in detail, it is instructive to present an example environment in which embodiments of the present invention may be implemented.

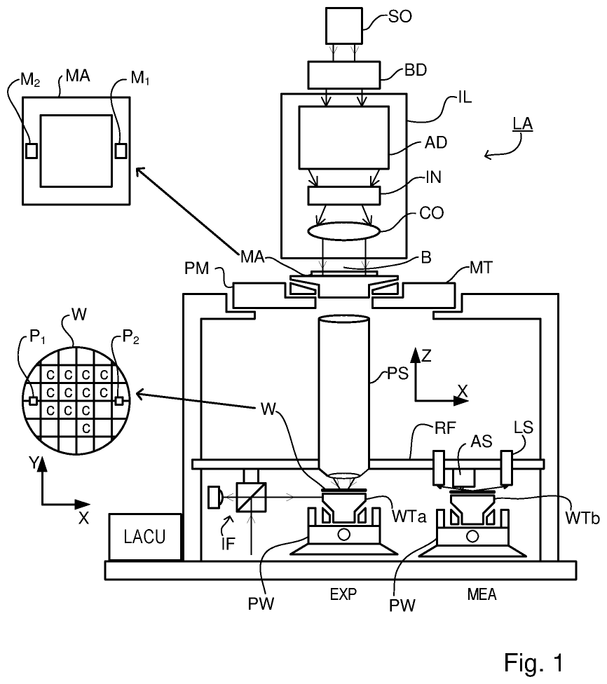

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit. As here depicted, the apparatus is of a transmissive type (e.g., employing a transmissive

patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations-an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

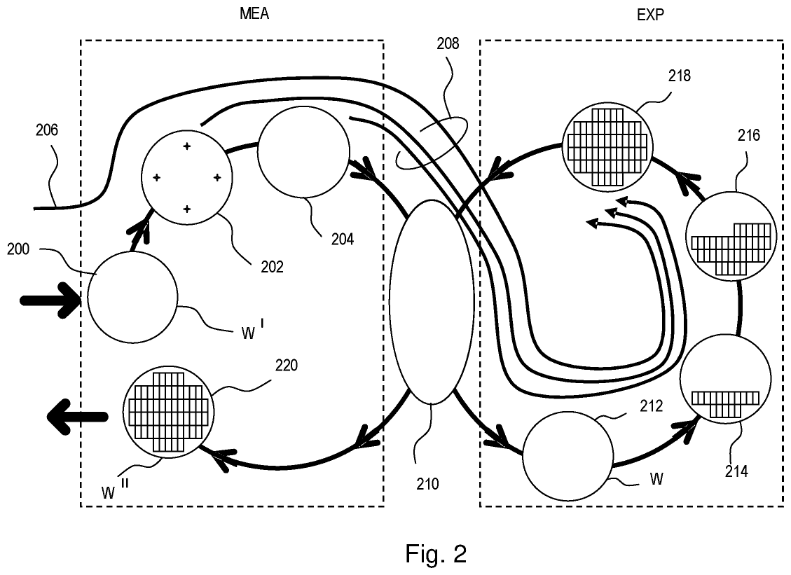

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus.

For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition. When substrate W′ was loaded, recipe data 206 were received, defining the exposures to be

performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In a lithography system, an important issue which has a significant impact on system up-time and therefore productivity is the ability to quickly and efficiently detect and/or diagnose events or trends (e.g., fault events) which might be indicative of irregular or abnormal behavior. It is of course always preferable to detect an issue before it causes a machine failure (failure event), such that any maintenance and downtime can be planned for and scheduled. Such predictive maintenance requires diagnostics to be performed at regular intervals so as to prevent unscheduled downs.

Lithography systems are very complex, comprising a number of different modules (e.g., including inter alia projection optics module, wafer stage module, reticle stage module, reticle masking module) each of which may be monitored. When a lithography system has an issue, one way of determining the root cause is to measure the frequency response function (e.g., the signal response per frequency in the frequency domain) of components or modules of the system. The frequency response may be compared to control data indicative of nominal lithographic system behavior, such as system population data from similar systems and/or to historic data from earlier measurements. Any significant difference in the frequency response can be used as an indicator of abnormal behavior; e.g., being indicative that the component is not functioning correctly.

For frequency response function analysis, the component inputs and outputs may be measured simultaneously to determine how the system changes the inputs to derive the outputs. For example, if the system is linear, which is a common assumption, then this change can be fully described by an frequency response function. In fact, for a linear and stable system, the response of the system to any input can be predicted from the frequency response function alone. However, system linearity is not a requirement and as such there are many approaches that are able to deal with nonlinearities while still generating a frequency response function, such as Best Linear Approximation approaches. As such, the methods disclosed herein apply equally to linear (or assumed linear) and/or non-linear systems. Frequency response functions are therefore (complex) transfer functions, expressed in the frequency- domain. Frequency response functions are well known in dynamic mechanical system or mechatronic analysis and will not be described in detail here.

To perform frequency response function analysis, excitation signals are injected into the system or component being analyzed and its output (signal response per frequency or frequency response) is measured. Because of the need to inject excitation signals, presently such frequency response function analysis is performed when no production is taking place so that the excitation signals do not disturb production performance and control accuracy during production. However, this means that it is required to schedule system downtime for such analysis. Also, such an approach does not allow for predictive maintenance as the frequency response function analyses are presently only run during setup and when a system is already known to have had an issue. This diagnostics downtime can be significant, particularly as multiple measurements should be made to obtain a good signal-to-noise ratio and good measurement quality.

It is therefore proposed to perform the frequency response function analyses and measure the frequency response functions inline, during actual production. This would appear to be a counterintuitive solution, as the necessary excitation signals need to be added to the system input (or component thereof), leading to a disturbance in system performance. However, the inventors have surmised that there are opportunities during production when such frequency response function analyses may be performed without negatively affecting system performance and particularly without affecting imaging positioning accuracy.

In particular, it is proposed to perform such frequency response function analyses at time periods during production which do not require highly accurate control (i.e., at time periods where the required control accuracy can be less stringent than, for example, during an exposure). In an embodiment, this may comprise performing such frequency response function analyses between exposures. For example, frequency response function analyses may be performed at periods during production when no actual (e.g., servo) performance is required. For example, where the system comprises two stages this may be done during chuck exchange (e.g., step 210 in FIG. 2, described above). Depending for example on the specific component being considered, other such periods may include performing a frequency response function analysis on the reticle stage while a wafer exchange takes place and/or on the wafer stage when a reticle is loaded. There are also cases (depending on the actual product detail) where the system may be either expose or measure limited, in which case either the measure or expose chuck is waiting for the other to finish.

Other opportunities may comprise during regularly performed maintenance actions such as M(X) actions. Such maintenance actions are performed routinely to maintain proper system performance. Such actions may relate to, for example, any one or more of: drift control, cleaning up disk space, various minor calibrations and/or (idle) condition monitoring actions.

As such, during suitable times during production, a frequency response measurement (e.g., a transfer measurement to determine the transfer function) can be performed at the same time and in parallel with the planned activity (e.g., a chuck transfer). The frequency response measurement data can be distinguished from the normal activity data. This can be done as there is a correlation between the (ideal) injected signals during, e.g., a movement, and the measured positioning signals. However, the measured position signals also comprise contributions that are not correlated to the injected signal, but to the actual move setpoint. By exploiting this correlation between the injected and movement signals, e.g., by computing the cross-or auto-power spectral density, proper frequency-responses can be computed without additional biases or variances due to the movement. Due to the nature of activities such as a chuck transfer, the excitation signals and therefore the frequency response measurement should not have any significant impact on such activities.

Because suitable (e.g., between-exposure) activities, such as chuck transfers, are performed frequently, there are sufficient opportunities to repeat such measurements to enable averaging to obtain a good quality frequency response function (good signal-to-noise ratio). As such, in an embodiment, it is proposed that such measurements are repeated a number of times and averaged.

The frequency response functions may be monitored, e.g., in real-time and/or during production. This may comprise comparing them to control data such as population data and/or historic data to monitor for any deviation indicative of and issue and/or problematic behavior. Based on the monitoring, a prediction can be made as to whether the system will keep on functioning correctly, normally and/or within specification (e.g., when the frequency response functions do not deviate from the control data significantly), or whether a problem is likely to be imminent and a service action should be scheduled. Hence, unscheduled downs can be prevented by including proper or appropriate maintenance actions during scheduled downs, as determined based on the frequency response functions.

In addition, if the system actually does go down, unscheduled (or any other non-nominal lithographic system behavior is detected), then actual data (e.g., historic data, e.g., as captured in parallel with the frequency response function data) will be available enabling faster diagnostics.

Because the methods disclosed herein may yield large amounts of data, an optional step may comprise downsampling one or more of the measured frequency response functions, e.g., by performing a fitting on the measured data. Such downsampling techniques are well-known in the art and any suitable downsampling technique may be used.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The breadth and scope of the present invention should not be limited by any of the above- described exemplary embodiments, but should be defined only in accordance with the following claims and their equivalents.

1.-19. (canceled)

20. A method for monitoring functioning of one or more components of a lithography system, the method comprising:
determining a frequency response function for each of the one or more components during production activity using the lithography system, at a time during the production activity when control requirements are at a first state;
evaluating each of the frequency response functions with respect to control data indicative of nominal lithographic system behavior; and
predicting whether to perform a maintenance action on the lithography system based on the evaluating step if the control requirements at the first state deviate from the control data indicative of nominal lithographic system behavior.

21. The method of claim 20, comprising scheduling and/or performing the maintenance action should the evaluation step indicate a deviation from the control data.

22. The method of claim 20, comprising not scheduling and/or performing the maintenance action should the evaluation step indicate no significant deviation from the control data.

23. The method of claim 20, wherein the determining a frequency response function for each of the one or more components is performed between exposure actions during that at least one pattern is actually exposed onto a substrate.

24. The method of claim 20, wherein the determining a frequency response function for each of the one or more components is performed at one or more periods during production when no servo performance is required.

25. The method of claim 20, wherein the determining a frequency response function for each of the one or more components is performed during a chuck transfer action where a chuck is transferred from a measurement side of the lithographic system to an exposure side of the lithographic system or transferred from the exposure side of the lithographic system to the measurement side of the lithographic system.

26. The method of claim 20, wherein the determining a frequency response function for each of the one or more components comprises one or both of:
performing a frequency response function analysis on a reticle stage during a substrate exchange; and/or
performing a frequency response function analysis on a wafer stage when a reticle is loaded to the reticle stage.

27. The method of claim 20, wherein the determining a frequency response function for each of the one or more components is performed during a maintenance action.

28. The method of claim 27, wherein the maintenance action comprises one or more of a drift control action, disk space cleanup, a calibration action and/or an idle condition monitoring action.

29. The method of claim 20, wherein the determining a frequency response function for each of the one or more components comprises injecting excitation signals into the one or more components and monitoring their frequency response.

30. The method as claimed in claim 29, further comprising:
determining a correlation between the injected excitation signals and movement signals of the one or more component; and
determining each the frequency-response functions based on the correlation so as to distinguish a frequency response due to the injected excitation signals from other signal contributions.

31. The method of claim 20, wherein the determining a frequency response function for each of the one or more components comprises performing the determination a plurality of times and averaging the determined frequency response functions per component.

32. The method of claim 20, comprising downsampling at least one of the frequency response functions.

33. The method of claim 20, comprising using one or more of the frequency response functions to perform a diagnostic action in the event of non-nominal lithographic system behavior and/or an unscheduled down.

34. A computer program product comprising non-transitory program instructions operable to perform the method of claim 20, when run on a suitable apparatus.

35. A processing arrangement, comprising:
the computer program product of claim 34; and
a processor operable to run the program instructions.

36. A lithographic system operable to perform the method of claims 20.

37. An integrated circuit manufactured with the lithographic system of claim 36.
